(19) United States
(12) Patent Application Publication
(10) Pub. No.: US 2015/0257269 A1
(43) Pub. Date: Sep. 10, 2015

(54) COMBINED WIRING BOARD

(71) Applicant: IBIDEN CO., LTD., Ogaki-shi (JP)

(72) Inventors: Teruyuki ISHIHARA, Ogaki-shi (JP); Michimasa Takahashi, Ogaki-shi (JP)

(73) Assignee: IBIDEN CO., LTD., Ogaki-shi (JP)

(21) Appl. No.: 14/636,780

(22) Filed: Mar. 3, 2015

(30) Foreign Application Priority Data
Mar. 5, 2014 (JP) 2014-042535

(51) Int. Cl. H05K 1/14

(52) U.S. Cl. CPC H05K 1/142; H05K 2201/2018

(57) ABSTRACT

A combined wiring board includes multiple metal frames arrayed in a first direction, and multiple wiring boards bonded to the metal frames such that the wiring boards are arrayed in the first direction. The metal frames directly or indirectly engage with the wiring boards such that each of the metal frames is positioned between two adjacent wiring boards of the wiring boards.

### CROSS-REFERENCE TO RELATED APPLICATIONS

The present application is based upon and claims the benefit of priority to Japanese Patent Application No. 2014-042535, filed Mar. 5, 2014, the entire contents of which are incorporated herein by reference.

### BACKGROUND OF THE INVENTION

1. Field of the Invention

The present invention relates to a combined wiring board obtained when multiple wiring boards are bonded together by using metal frames.

2. Description of Background Art

JP2011-23657A describes a multi-piece wiring board accommodation kit made up of multiple piece wiring boards and a frame that has accommodation holes to accommodate the multiple piece wiring boards. The entire contents of this publication are incorporated herein by reference.

### SUMMARY OF THE INVENTION

According to one aspect of the present invention, a combined wiring board includes multiple metal frames arrayed in a first direction, and multiple wiring boards bonded to the metal frames such that the wiring boards are arrayed in the first direction. The metal frames directly or indirectly engage with the wiring boards such that each of the metal frames is positioned between two adjacent wiring boards of the wiring boards.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a plan view of a multipiece printed wiring board;

FIG. 2 is a perspective view of an individually cut-out printed wiring board;

FIGS. 3(A) and 3(B) are perspective views of a printed wiring board being processed by a laser;

FIGS. 4(A) and 4(B) are plan views showing printed wiring boards supported by each metal frame;

FIG. 5 is a plan view of a metal frame;

FIG. 6 is a plan view of a crimped printed wiring board;

FIGS. 7(A) and 7(B) are cross-sectional views showing part of a combined wiring board;

FIGS. 8(A) and 8(B) are cross-sectional views of a crimping machine in a first embodiment;

FIGS. 9(A) and 9(B) are cross-sectional views of a crimping machine in a first modified example of the first embodiment;

FIG. 10 is a plan view of a printed wiring board cut out from a combined wiring board;

FIG. 11 is a cross-sectional view showing a printed wiring board of the first embodiment;

FIG. 12 is a cross-sectional view showing a printed wiring board of the first embodiment with mounted electronic components;

FIG. 13 is a plan view of a combined wiring board according to a second embodiment; and

FIG. 14 is a plan view of a combined wiring board according to a first modified example of the second embodiment.

### DETAILED DESCRIPTION OF THE EMBODIMENTS

The embodiments will now be described with reference to the accompanying drawings, wherein like reference numerals designate corresponding or identical elements throughout the various drawings.

### First Embodiment

Combined wiring board 100 of the present embodiment is structured to fix multiple printed wiring boards 10 to metal frames positioned alternately with the printed wiring boards to be reflowed and prevents warping in printed wiring boards 10 during a reflow process for mounting electronic components.

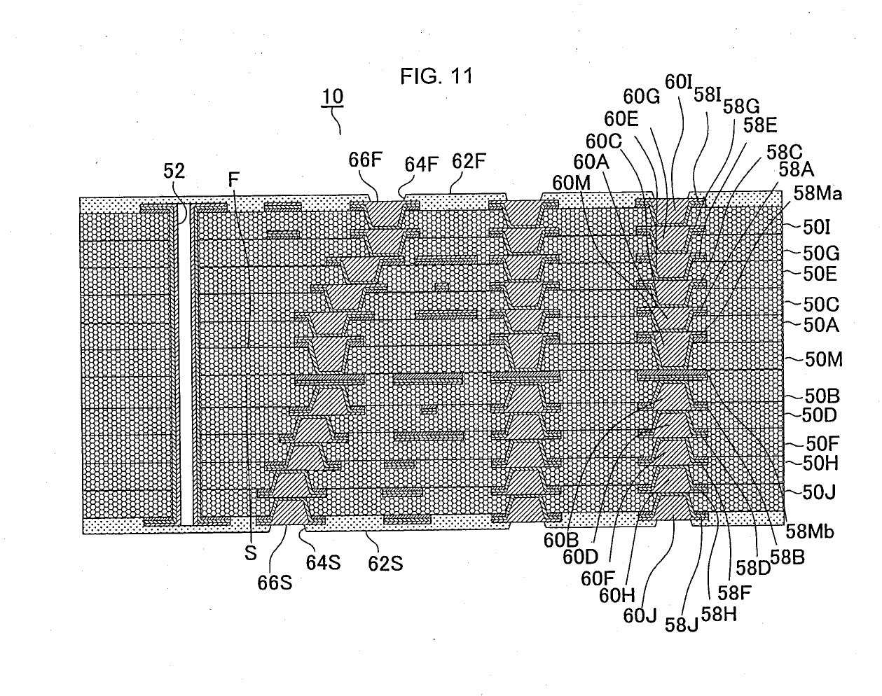

FIG. 11 is a cross-sectional view of printed wiring board 10 of the first embodiment before electronic components are mounted. In printed wiring board 10, interlayer insulation layers (50A, 50C, 50E, 50G, 50I) are laminated on the upper surface (first surface) (F) side of core insulation layer (50M) positioned in the center, while interlayer insulation layers (50B, 50D, 50F, 50H, 50J) are laminated on the lower surface (second surface) (S) side. Conductive circuits (58Ma) on first surface (F) of core insulation layer (50M) are connected to conductive circuits (58Mb) on second surface (S) by via conductors (60M). Core material is positioned in core insulation layer (50M), and core material is also positioned in each of interlayer insulation layers (50A, 50C, 50E, 50G, 50I) and interlayer insulation layers (50B, 50D, 50F, 50H, 50J).

In interlayer insulation layer (50A) laminated on the first-surface (F) side of core insulation layer (50M), via conductors (60A) are formed to connect conductive circuits (58A) on interlayer insulation layer (50A) to conductive circuits (58Ma) of core insulation layer (50M). In interlayer insulation layer (50C) laminated on interlayer insulation layer (50A), via conductors (60C) are formed to connect conductive circuits (58C) on interlayer insulation layer (50C) to conductive circuits (58A) on interlayer insulation layer (50A). In interlayer insulation layer (50E) laminated on interlayer insulation layer (50C), via conductors (60E) are formed to connect conductive circuits (58E) on interlayer insulation layer (50E) to conductive circuits (58C) on interlayer insulation layer (50C). In interlayer insulation layer (50G) laminated on interlayer insulation layer (50E), via conductors (60G) are formed to connect conductive circuits (58G) on interlayer insulation layer (50G) to conductive circuits (58E) on interlayer insulation layer (50E). In interlayer insulation layer (50I) laminated on interlayer insulation layer (50G), via conductors (601) are formed to connect conductive circuits (581) on interlayer insulation layer (50I) to conductive circuits (58G) on interlayer insulation layer (50G). On interlayer insulation layer (50I), solder-resist layer (62F) is formed, and conductive circuits (581) exposed in openings (64F) of the solder-resist layer work as pads (66F).

In interlayer insulation layer (50B) laminated on the second-surface (S) side of core insulation layer (50M), via conductors (60B) are formed to connect conductive circuits (58B) on interlayer insulation layer (50B) to conductive circuits (58Mb) of core insulation layer (50M). In interlayer insulation layer (50D) laminated on interlayer insulation layer (50B), via conductors (60D) are formed to connect conductive circuits (58D) on interlayer insulation layer (50D) to conductive circuits (58B) on interlayer insulation layer (50B). In interlayer insulation layer (50F) laminated on interlayer insulation layer (50D), via conductors (60F) are formed to connect conductive circuits (58F) on interlayer insulation layer (50F) to conductive circuits (58D) on interlayer insulation layer (50D). In interlayer insulation layer (50H) laminated on interlayer insulation layer (50F), via conductors (60H) are formed to connect conductive circuits (58H) on interlayer insulation layer (50H) to conductive circuits (58F) on interlayer insulation layer (50F). In interlayer insulation layer (50J) laminated on interlayer insulation layer (50H), via conductors (60J) are formed to connect conductive circuits (58J) on interlayer insulation layer (50J) to conductive circuits (58H) on interlayer insulation layer (5014). On interlayer insulation layer (50J), solder-resist layer (62S) is formed, and conductive circuits (58J) exposed in openings (64S) of the solder-resist layer work as pads (66S). Through holes 52 are formed to penetrate through interlayer insulation layers (50I, 50G, 50E, 50C, 50A, 50M, 50B, 50D, 50F, 50H, 50J).

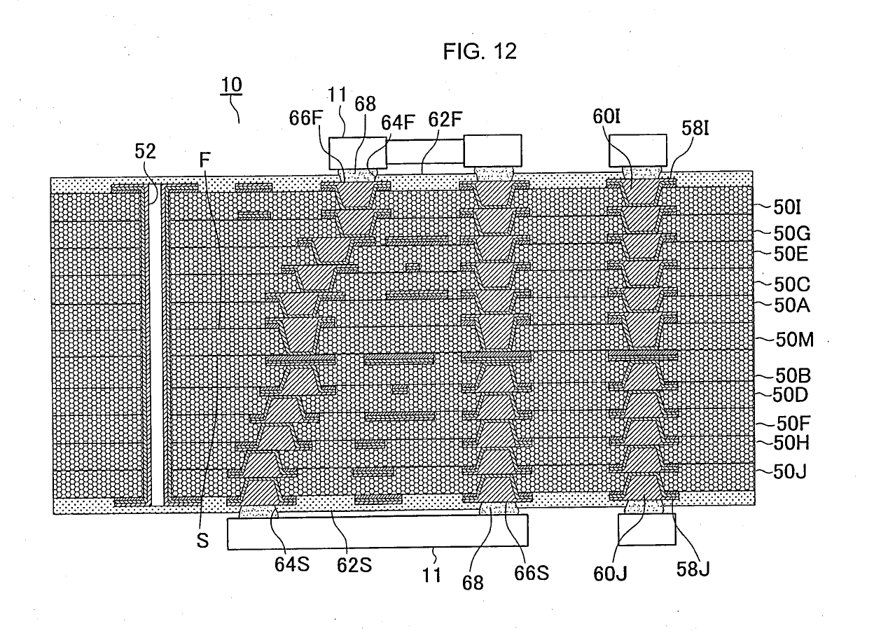

FIG. 12 is a cross-sectional view of printed wiring board 10 with mounted electronic components 11. Electronic component 11 is mounted through solder 68 provided on pads (66F) on the first-surface (F) side of printed wiring board 10. Electronic component 11 is mounted through solder 68 provided on pads (66S) on the second-surface (S) side of printed wiring board 10.

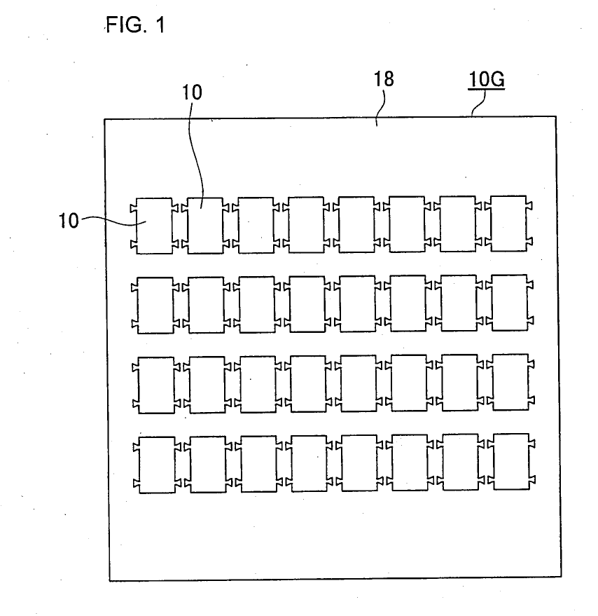

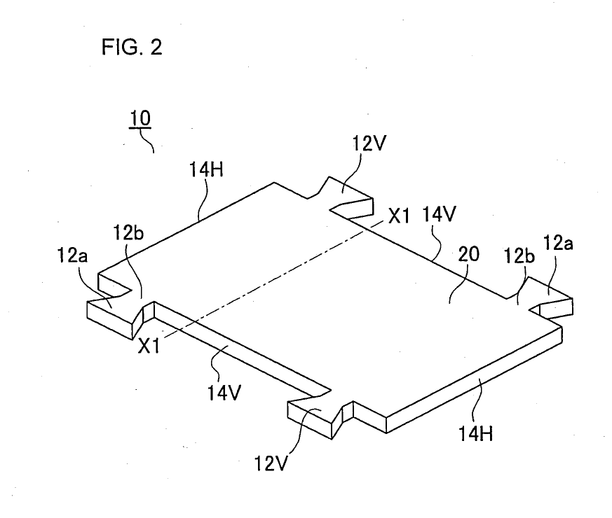

FIG. 1 is a plan view of multipiece printed wiring board (10G) where printed wiring boards 10 are formed in an 8×4 array. FIG. 2 is a perspective view of printed wiring board 10 cut out as an individual piece. FIG. 11 shows part of a cross section cut along X1-X1 in FIG. 2. As shown in FIG. 1, multiple printed wiring boards 10 are manufactured inside peripheral frame 18 of multipiece printed wiring board (10G). As shown in FIG. 2, rectangular main body 20 is formed in printed wiring board 10 to have longitudinal sidewall (14V) and lateral sidewall (14H). Two support pieces (12V) are formed on each longitudinal sidewall (14V) to face each other sandwiching main body 20. A support piece (12V) is made up of rectangular base (bridge portion) (12b) and trapezoidal portion (12a) with a width increasing toward its tip.

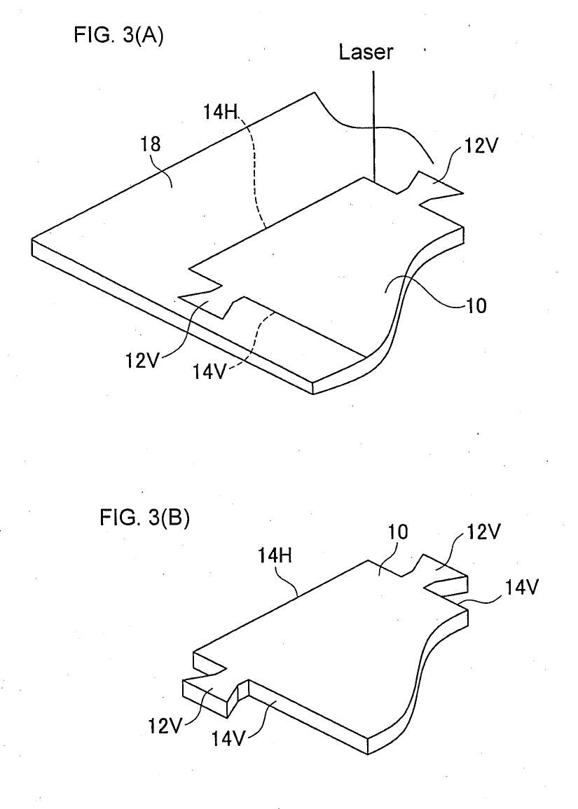

In the first embodiment, printed wiring board 10 is cut out along its outline by a laser as shown in FIG. 3(A) when it is cut out from multipiece printed wiring board (10G) so that printed wiring board 10 is obtained as an individual piece as shown in FIG. 3(B).

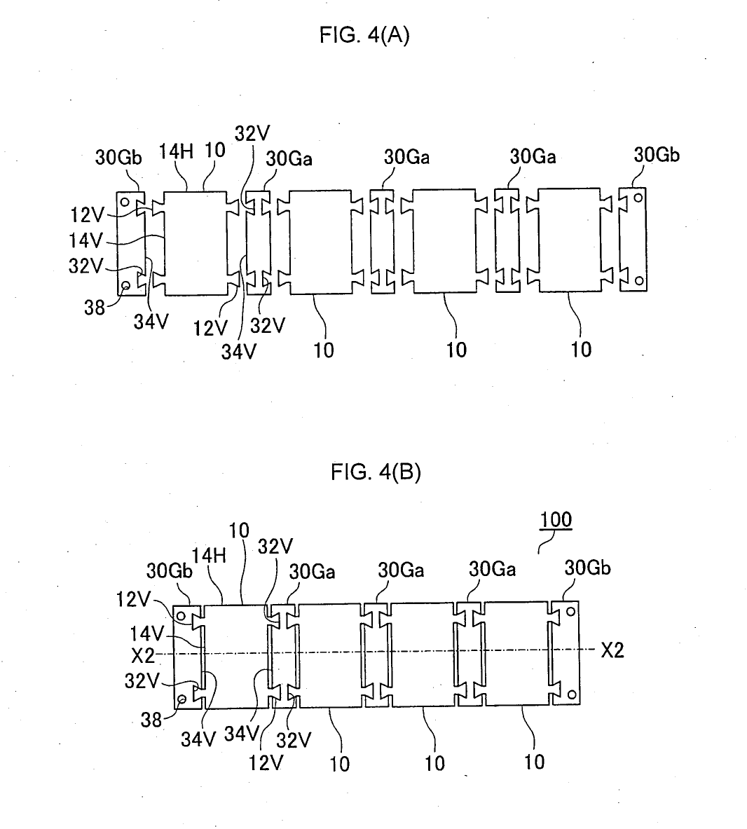

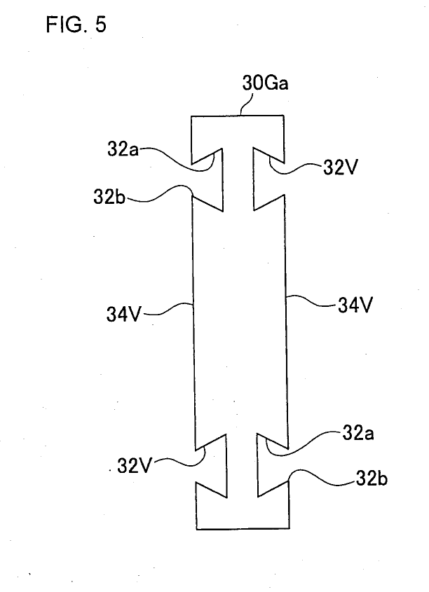

FIG. 4(A) is a plan view showing printed wiring boards 10 prior to being supported by metal frames (30Ga, 30Gb), and FIG. 4(B) is a plan view showing printed wiring boards 10 supported by metal frames (30Ga, 30Gb). FIG. 5 is a plan view of metal frame (30Ga).

In the present embodiment, combined wiring board 100 is provided with four printed wiring boards 10 and five metal frames; the five metal frames are positioned alternately among the four printed wiring boards arrayed in one direction in such a way that both sides of a printed wiring board 10 in that array are bonded to metal frames, as shown in FIGS. 4A and 4B. The metal frames are each made of aluminum, and there are metal frame (30Ga) to which the periphery of printed wiring board 10 is bonded on both of its sides and metal frame (30Gb) to which the periphery of printed wiring board 10 is bonded only on one side.

In metal frame (30Ga), two slits (32V) each corresponding to support piece (12V) of printed wiring board 10 are formed in each vertical wall (34V) on either periphery corresponding to longitudinal sidewall (14V) of printed wiring board 10, as shown in FIG. 5. Slit (32V) is made up of base (32b) corresponding to rectangular base (bridge portion) (12b) of support piece (12V) of printed wiring board 10 and of trapezoidal portion (32a) corresponding to trapezoidal portion (12a) of support piece (12V) of printed wiring board 10. Trapezoidal portion (32a) is formed to have a width that decreases toward base (32b).

In metal frame (30Gb), two slits (32V) the same as in metal frame (30Ga) are formed in vertical wall (34V) of either periphery corresponding to longitudinal sidewall (14V) of printed wiring board 10. Metal frame (30Gb) is formed to be bonded to a side of printed wiring board 10 positioned on either end of the array. In addition, along the periphery of the side where no slit (32V) is formed, two alignment holes 38 are formed.

In each of metal frames (30Ga, 30Gb) positioned in one array, the length of vertical wall (34V) corresponding to longitudinal sidewall (14V) of wiring board 10 is formed to be substantially the same as the length of longitudinal sidewall (14V). In addition, each slit (32V) is formed to have a predetermined clearance between vertical wall (34V) and longitudinal sidewall (14V) supported by support piece (12V) (see FIG. 4(B)).

As shown in FIG. 4(B), support pieces (12V) of printed wiring boards 10 are fit into slits (32V) so that printed wiring boards 10 and metal frames (30Ga) are alternately positioned in a direction in which they are arrayed, while metal frame (30Gb) is positioned on each of both ends of that array. Accordingly, printed wiring boards 10 are supported by metal frames (30Ga, 30Gb) from both sides in the direction in which they are arrayed.

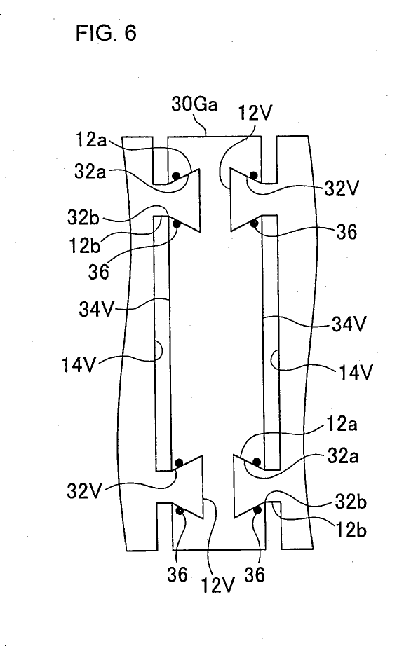

FIG. 6 shows a state where printed wiring boards 10 are bonded to both sides of a metal frame (30Ga) through a crimping process.

In metal frames (30Ga, 30Gb), crimped portions 36 are formed using crimping machine 200 along the periphery adjacent to support piece (12V) at the border of base (32b) and trapezoidal portion (32a) of slit (32V), as shown in FIG. 6. Because of plastic deformation caused by crimped portions 36, the sidewall of slit (32V) abuts, and is bonded to, the sidewall of support piece (12V). As a result, printed wiring boards 10 are bonded (fixed) to metal frames (30Ga, 30Gb).

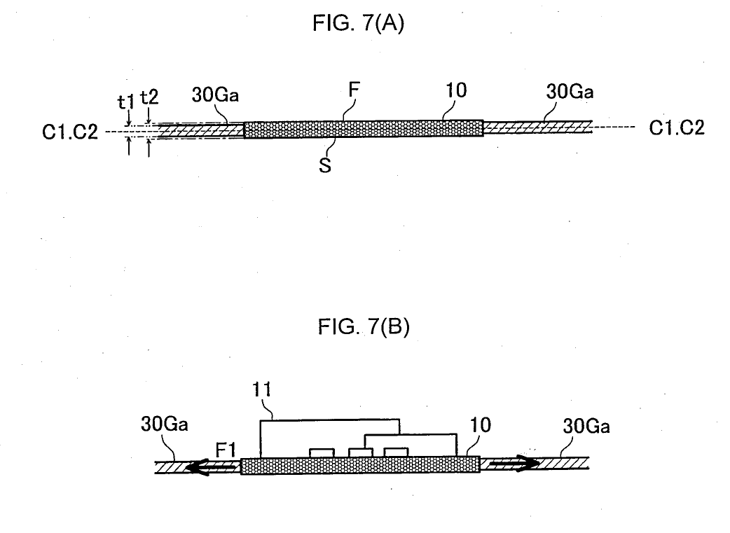

FIG. 7(A) shows part of a cross section taken along (X2-X2) of printed wiring board 10 in FIG. 4(B). Metal frames (30Ga, 30Gb) are each set to have a thickness (t1) of 750 μm. Printed wiring board 10 is set to have a thickness (t2) of 780 μm. Namely, metal frames (30Ga, 30Gb) are set to be thinner than printed wiring board 10. In addition, printed wiring board 10 is bonded to metal frames (30Ga, 30Gb) in such a way that its central plane (C2) in a thickness direction corresponds to central plane (C1) of metal frames (30Ga, 30Gb) in the thickness direction, as shown in FIG. 7(A).

Accordingly, metal frames (30Ga, 30Gb) are positioned lower than first surface (F) of printed wiring board 10 while they are also positioned lower than second surface (S) of printed wiring board 10. As a result, metal frames (30Ga, 30Gb) do not interfere with the procedure of mounting electronic components on printed wiring board 10.

The coefficient of thermal expansion (CTE) along the main surfaces of metal frames (30Ga, 30Gb) made of aluminum is 23 ppm/° C. and the CTE along the main surface of printed wiring board 10 made of resin is 16 ppm/° C. That is, the CTE of metal frames (30Ga, 30Gb) is higher than the CTE of printed wiring board 10. By setting metal frames (30Ga, 30Gb) to be thinner than printed wiring board 10, warping caused by the difference in CTEs is suppressed from occurring in printed wiring boards 10. In the first embodiment, aluminum was used as a material to form metal frames (30Ga, 30Gb). However, the material may be copper, stainless steel or the like as long as its CTE is higher than that of printed wiring board 10.

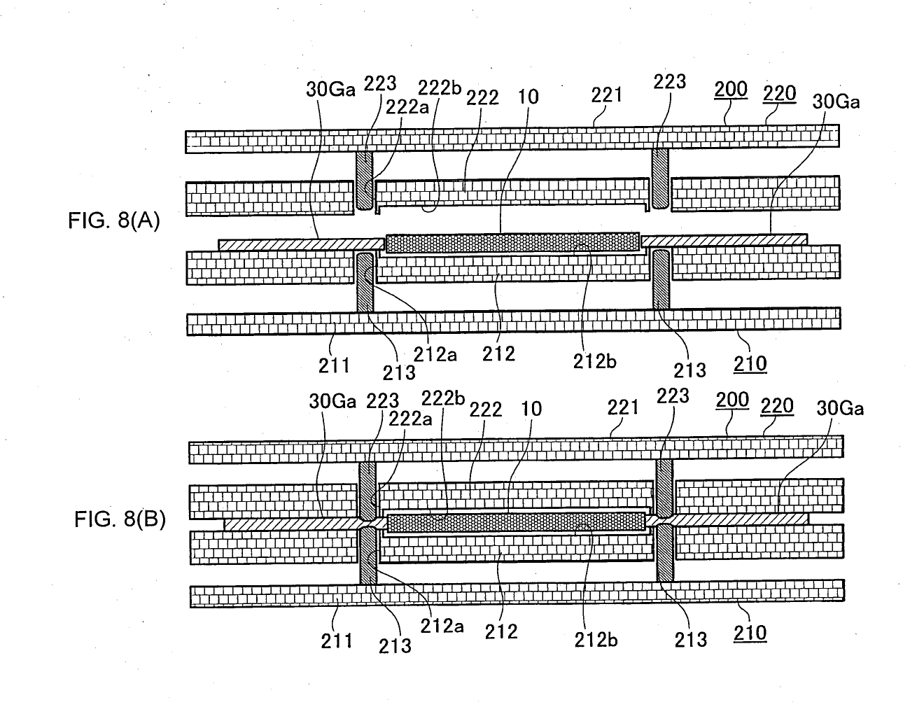

FIG. 8(A) is a cross-sectional view of crimping machine 200 to conduct a crimping process on metal frames (30Ga, 30Gb).

Crimping machine 200 conducts a crimping process on metal frames (30Ga, 30Gb) that support printed wiring boards 10 by fitting support pieces (12V) into slits (32V).

Crimping machine 200 includes lower die 210 and upper die 220. Lower die 210 is provided with base 211 and support plate 212, and support plate 212 is supported to be vertically movable relative to base 211. Crimping punches 213 are formed in base 211, and penetrating holes (212a) to allow punches 213 to go through are formed in support plate 212. In the center of support plate 212, recess (212b) is formed so that no force is exerted on printed wiring board 10 during the crimping process. Printed wiring board 10 is placed on recess (212b), and metal frames (30Ga, 30Gb) are placed on support plate 212.

Upper die 220 includes base 221 and support plate 222. Support plate 222 is supported to be vertically movable relative to base 221. Crimping punches 223 are formed in base 221, and penetrating holes (222a) to allow punches 223 to go through are formed in support plate 222. Recess (222b) is formed in the center of support plate 222 so that no force is exerted on printed wiring board 10 during the crimping process.

FIG. 8(B) shows a state in which upper die 220 is pressed against lower die 210, punch 223 of upper die 220 is pressed against the upper surface of metal frame (30Ga), and punch 213 of lower die 210 is pressed against the lower surface of metal frame (30Ga). Using crimping machine 200, crimped portions 36 shown in FIG. 6 are each formed simultaneously in metal frames (30Ga, 30Gb) which are set as shown in FIG. 4(B). Printed wiring board 10 is bonded to metal frames (30Ga, 30Gb) by crimped portions 36 formed as above. Accordingly, printed wiring boards 10 are bonded to metal frames (30Ga, 30Gb) on both of their sides in the array in which they are positioned, and combined wiring board 100 ready for reflow is completed.

In combined wiring board 100 of the first embodiment, printed wiring boards 10 are bonded to metal frames (30Ga, 30Gb) on both of their sides in the array in which they are positioned. Accordingly, warping is less likely to occur in printed wiring boards 10 because of the difference in the CTE of printed wiring boards 10 and the CTE of metal frames (30Ga, 30Gb). Especially, in metal frames (30Ga, 30Gb), it is sufficient if the length of vertical wall (34V) corresponding to longitudinal sidewall (14V) of printed wiring board 10 is substantially the same length as that of longitudinal sidewall (14V) in the direction in which they are arrayed. Thus, the number of metal frames per unit area can be set greater, compared with a structure where a metal frame is formed to surround printed wiring board 10. In addition, since printed wiring boards 10 and metal frames (30Ga) are alternately positioned and bonded to each other, there are fewer variations in warping caused by different positions (for example, at end and center) in combined wiring board 100 than in a structure where multiple wiring boards are bonded to one metal frame. Accordingly, differences in the effects of reducing warping are smaller. Moreover, by changing the number of metal frames (30Ga) positioned between wiring boards, it is easy to adjust the number of wiring boards 10 in combined wiring board 100. Thus, the mounting efficiency of components on wiring boards is enhanced.

Since crimped portions 36 are formed simultaneously on the peripheral portions of slits (32V) of metal frames (30Ga, 30Gb), printed wiring boards 10 are accurately aligned to metal frames (30Ga, 30Gb). Also, positional deviations among printed wiring boards are minimized.

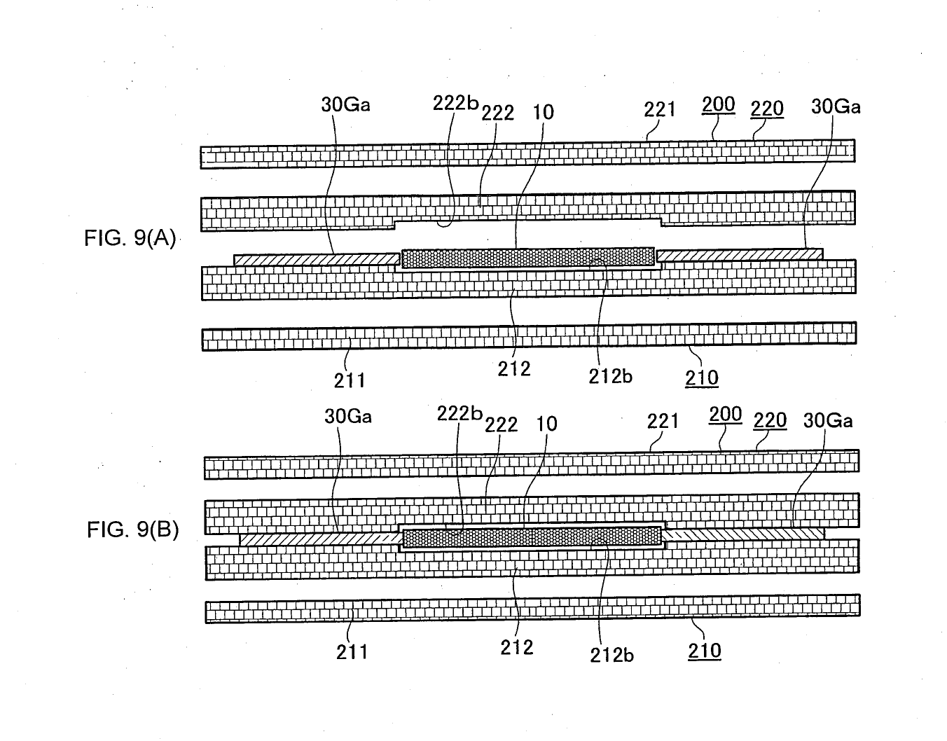

FIG. 9 is a cross-sectional view of crimping machine 200 according to a first modified example of the first embodiment. In the first modified example, punches are not used, and metal frames (30Ga, 30Gb) entirely undergo plastic deformation by using support plate 222 of upper die 220 and support plate 212 of lower die 210 so that vertical walls (34V) of metal frames (30Ga, 30Gb) are bonded to printed wiring boards 10.

Solder is printed after printed wiring boards 10 are bonded to metal frames (30Ga, 30Gb) through a crimping process (see FIG. 6), and electronic components 11 or the like are placed and reflowed in a reflow oven. Accordingly, electronic components 11 or the like are mounted on the wiring boards. Since the reflow temperature close to 200° C. exceeds the glass transition temperature (Tg) of the resin in printed wiring boards 10, warping tends to occur in printed wiring boards 10 because of the weight of mounted electronic components 11 and stress remaining in the wiring boards. Here, stress toward the center of printed wiring boards 10, along with stress caused by the weight of electronic components 11 or the like, is exerted on printed wiring boards 10 bonded to metal frames (30Ga, 30Gb) in the first embodiment as shown in FIG. 7B. As described above, since the CTE along the main surfaces of metal frames (30Ga, 30Gb) is higher than the CTE of printed wiring boards 10, metal frames (30Ga, 30Gb) each expand in a planar direction more than printed wiring boards 10. As a result, outward stress (F1) works on printed wiring boards 10 by way of support pieces (12V) to cancel out the aforementioned stress toward the center. Accordingly, warping is unlikely to occur in printed wiring boards 10 during a reflow process.

Printed wiring board 10 according to a second modified example of the first embodiment has a structure shown in FIG. 12 and core material is provided in core insulation layer (50M), whereas core material is not provided in interlayer insulation layers (50A, 50C, 50E, 50G, 50I) or in interlayer insulation layers (50B, 50D, 50F, 50H, 50J). Thus, warping tends to occur in printed wiring boards 10, but because of metal frames (30Ga, 30Gb), warping is unlikely to occur in printed wiring board 10 during a reflow process.

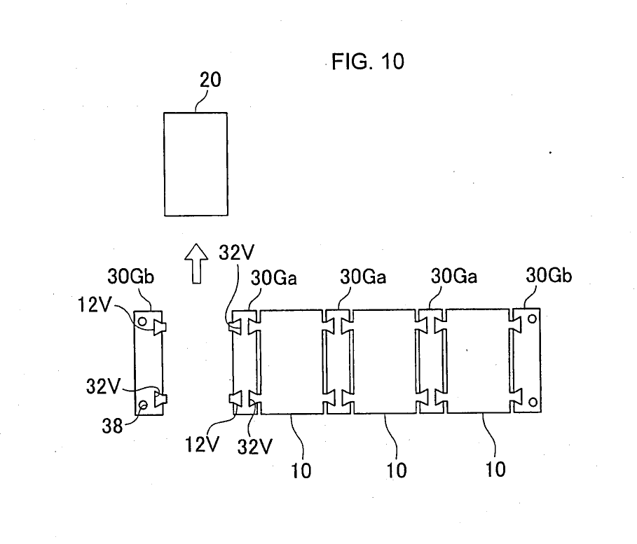

FIG. 10 is a plan view showing printed wiring board 10 cut out from combined wiring board 100. After electronic components are mounted, rectangular main body 20 is cut out from support pieces (12V) of printed wiring board 10. Main body 20 of printed wiring board 10 is separated from metal frames (30Ga, 30Gb), leaving support pieces (12V) in slits (32V).

### Second Embodiment

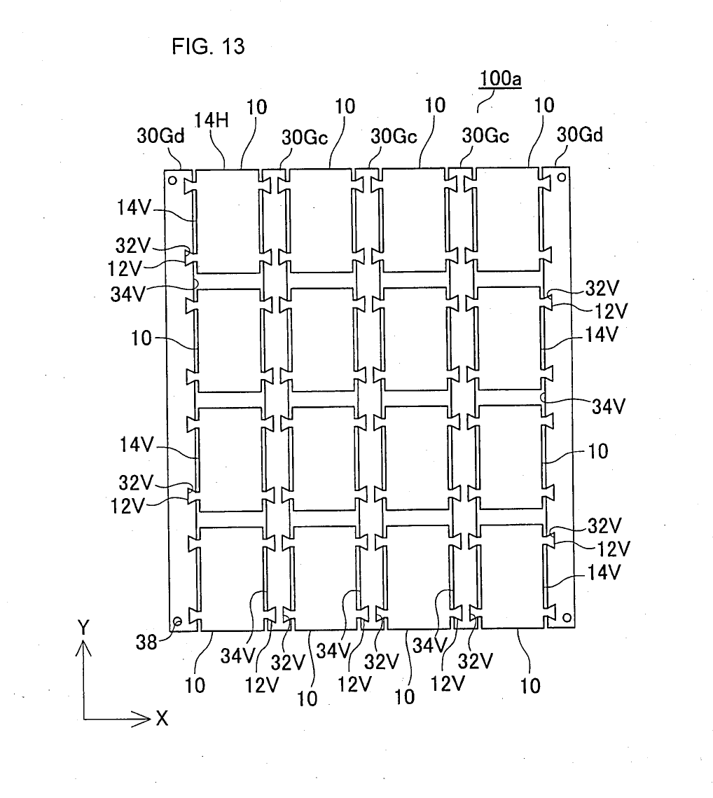

FIG. 13 shows combined wiring board (100a) according to a second embodiment.

In combined wiring board (100a) of the second embodiment, multiple printed wiring boards 10 in a 2-D array are bonded to metal frames (30Gc, 30Gd) as shown in FIG. 13. Eight slits (32V) to hold support pieces (12V) of four printed wiring boards 10 are formed along vertical wall (34V) on each of both sides of metal frame (30Gc). Eight slits (32V) to hold support pieces (12V) of four printed wiring boards 10 are formed along vertical wall (34V) on one side of metal frame (30Gd), whereas two alignment holes 38 are formed on the periphery of the other side of metal frame (30Gd), where no slits (32V) are formed, as shown in FIG. 13.

In the second embodiment, support pieces (12V) on either side of four printed wiring boards 10 arrayed in a direction (direction Y in FIG. 13) perpendicular to the direction in FIG. 4 (direction X in FIG. 13) are bonded to metal frame (30Gc) or metal frame (30Gd). Accordingly, more printed wiring boards 10 can be bonded in a limited space.

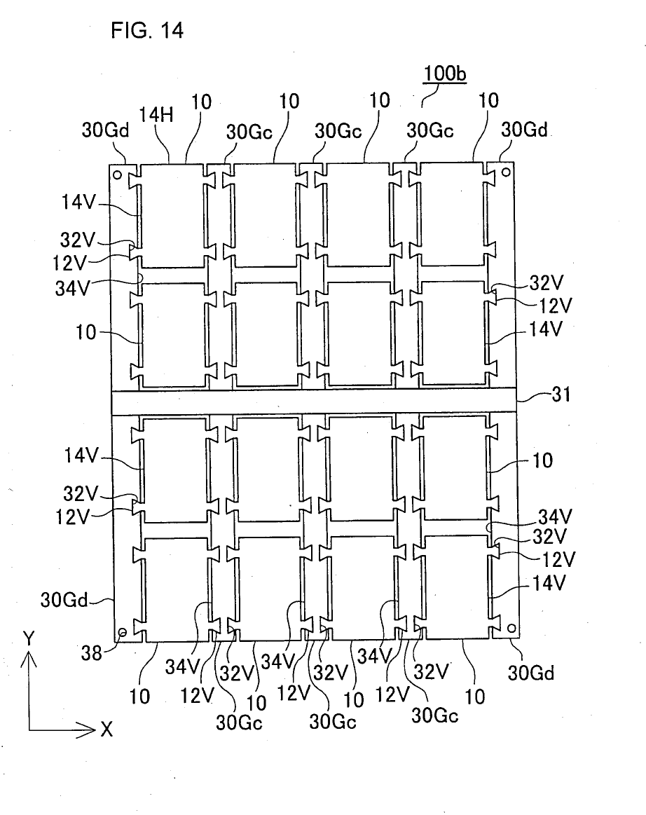

FIG. 14 is a plan view showing combined wiring board (100b) according to a first modified example of the second embodiment. In the first modified example, metal frames (30Gc, 30Gd) bonded to printed wiring boards 10 arrayed in multiple rows (upper rows in the example shown in FIG. 14) are connected to metal frames (30Gc, 30Gd) bonded to printed wiring boards 10 arrayed in other multiple rows (lower rows in the example shown in FIG. 14) by metal connection piece 31. No printed wiring board 10 is bonded to connection piece 31. Accordingly, even when more printed wiring boards 10 are bonded to metal frames (30Gc, 30Gd), since metal frames (30Gc, 30Gd) are strongly connected to each other, warping is certainly suppressed from occurring in printed wiring boards 10 because of metal frames (30Gc, 30Gd).

The present invention is not limited to the embodiments described above. For example, the present invention may also be embodied as described below. Also, the structure in detail may be modified properly within the scope of the gist of the present invention.

(1) In the first embodiment, metal frames (30Gb) on both ends and three metal frames (30Ga) are alternately positioned with four printed wiring boards 10. However, that is not the only option; metal frames (30Gb) on both ends and “N” number of metal frames (30Ga) may be alternately positioned with “N+1” number of printed wiring boards 10. Also, in the same manner, metal frames (30Gd) on both ends and “N” number of metal frames (30Gc) may be alternately positioned with multiple printed wiring boards 10 in the second embodiment.

(2) In the second embodiment, support pieces (12V) on one side of four printed wiring boards 10 are bonded to one metal frame (30Gc) or (30Gd). However, that is not the only option; support pieces (12V) on one side of two, three, or five or more printed wiring boards 10 may be bonded to one metal frame (30Gc) or (30Gd).

(3) In each of the above embodiments, printed wiring boards 10 are bonded to metal frames by support pieces (12V) fitted into slits (32V). However, printed wiring boards 10 may also be bonded to metal frames by connecting, for example, a portion formed on longitudinal sidewall (14V) to a portion formed on vertical wall (34V) of a metal frame.

(4) In the above embodiments, the frame portions made up of metal frames (30Ga, 30Gb) or metal frames (30Gc, 30Gd) are preferred to have higher rigidity at solder reflow temperature than the piece portions of printed wiring boards 10.

When an electronic component is being mounted on a wiring board, the solder reflow temperature exceeds the glass transition temperature (Tg) of the material in the wiring board. Thus, problems arise such as warping in the wiring board caused by the weight of the mounted electronic component and stress remaining in the wiring board.

A combined wiring board according to an embodiment of the present invention prevents printed wiring boards from warping during a reflow process for mounting electronic components.

A combined wiring board according to one aspect of the present invention is characterized by having multiple wiring boards and multiple metal frames. In such a combined wiring board, multiple wiring boards are arrayed in one direction and multiple metal frames are positioned between wiring boards, and a metal frame is bonded to each of both sides of a wiring board arrayed in the one direction.

In a combined wiring board according to an embodiment of the present invention, both sides of wiring boards that are arrayed in one direction are bonded to metal frames. Thus, warping is less likely to occur in the wiring boards. Especially, since it is sufficient if the length of the wall portion of a metal frame facing a wiring board in the direction in which they are arrayed is approximately the same length as the wall portion of the wiring board, the number of metal frames per unit area can be set greater, compared with a structure using a metal frame to surround a wiring board. In addition, since wiring boards and metal frames are alternately positioned when they are bonded, compared with a metal frame to which multiple wiring boards are bonded, there are fewer variations in warping caused by different positions of wiring boards in the combined wiring board (for example, at an end position or central position). As a result, differences are smaller in the effects of reducing warping. Moreover, since the number of wiring boards in one combined wiring board is easy to adjust by changing the number of metal frames to be positioned between wiring boards, efficiency is high when components are mounted on wiring boards.

Obviously, numerous modifications and variations of the present invention are possible in light of the above teachings. It is therefore to be understood that within the scope of the appended claims, the invention may be practiced otherwise than as specifically described herein.

What is claimed is:

1. A combined wiring board, comprising:
a plurality of metal frames arrayed in a first direction; and
a plurality of wiring boards bonded to the plurality of metal frames such that the plurality of wiring boards is arrayed in the first direction,
wherein the plurality of metal frames is configured to directly or indirectly engage with the plurality of wiring boards such that each of the metal frames is positioned between two adjacent wiring boards of the plurality of wiring boards.

2. A combined wiring board according to claim 1, wherein the plurality of metal frames is configured to directly or indirectly engage with a plurality of second wiring boards in a second direction perpendicular to the first direction.

3. A combined wiring board according to claim 1, wherein each of the wiring boards has two opposing sides configured to directly or indirectly engage with the plurality of metal frames arrayed in the first direction.

4. A combined wiring board according to claim 1, further comprising:
a pair of metal frames bonded to two end wiring boards of the wiring boards arrayed in the first direction,
wherein the pair of metal frames is configured to directly or indirectly engage with the two end wiring boards of the wiring boards arrayed in the first direction.

5. A combined wiring board according to claim 1, wherein the plurality of metal frames has a coefficient of thermal expansion in a planar direction of the metal frames which is greater than a coefficient of thermal coefficient of the plurality of wiring boards in a planar direction of the wiring boards.

6. A combined wiring board according to claim 2, wherein each of the wiring boards has two opposing sides configured to directly or indirectly engage with the plurality of metal frames arrayed in the first direction.

7. A combined wiring board according to claim 2, further comprising:
a pair of metal frames bonded to two end wiring boards of the wiring boards arrayed in the first direction,
wherein the pair of metal frames is configured to directly or indirectly engage with the two end wiring boards of the wiring boards arrayed in the first direction.

8. A combined wiring board according to claim 2, wherein the plurality of metal frames has a coefficient of thermal expansion in a planar direction of the metal frames which is greater than a coefficient of thermal coefficient of the plurality of wiring boards in a planar direction of the wiring boards.

9. A combined wiring board according to claim 3, further comprising:
a pair of metal frames bonded to two end wiring boards of the wiring boards arrayed in the first direction,
wherein the pair of metal frames is configured to directly or indirectly engage with the two end wiring boards of the wiring boards arrayed in the first direction.

10. A combined wiring board according to claim 3, wherein the plurality of metal frames has a coefficient of thermal expansion in a planar direction of the metal frames which is greater than a coefficient of thermal coefficient of the plurality of wiring boards in a planar direction of the wiring boards.

11. A combined wiring board according to claim 4, wherein the plurality of metal frames has a coefficient of thermal expansion in a planar direction of the metal frames which is greater than a coefficient of thermal coefficient of the plurality of wiring boards in a planar direction of the wiring boards.

12. A combined wiring board according to claim 1, wherein each of the metal frames has a plurality of crimped portions bonding two of the wiring boards.

13. A combined wiring board according to claim 1, wherein each of the metal frames has a plurality of crimped portions formed by plastic deformation such that the plurality of crimped portions of each of the metal frames is bonding two of the wiring boards.

14. A combined wiring board according to claim 1, wherein each of the wiring boards is a multilayer wiring board.

15. A combined wiring board according to claim 1, wherein each of the wiring boards has a plurality of support portions, and each of the metal frames has a plurality of slit portions configured to directly or indirectly engage with the plurality of support portions of the wiring boards.

16. A combined wiring board according to claim 12, wherein each of the wiring boards has a plurality of support portions, and each of the metal frames has a plurality of slit portions configured to directly or indirectly with the plurality of support portions of the wiring boards.

17. A combined wiring board according to claim 13, wherein each of the wiring boards has a plurality of support portions, and each of the metal frames has a plurality of slit portions configured to directly or indirectly engage with the plurality of support portions of the wiring boards.

18. A combined wiring board according to claim 12, wherein the plurality of metal frames has a coefficient of thermal expansion in a planar direction of the metal frames which is greater than a coefficient of thermal coefficient of the plurality of wiring boards in a planar direction of the wiring boards.

19. A combined wiring board according to claim 13, wherein the plurality of metal frames has a coefficient of thermal expansion in a planar direction of the metal frames which is greater than a coefficient of thermal coefficient of the plurality of wiring boards in a planar direction of the wiring boards.

20. A combined wiring board according to claim 14, wherein the plurality of metal frames has a coefficient of thermal expansion in a planar direction of the metal frames which is greater than a coefficient of thermal coefficient of the plurality of wiring boards in a planar direction of the wiring boards.
